(19) United States
(12) Patent Application Publication
(10) Pub. No.: US 2009/0189055 A1
(43) Pub. Date: Jul. 30, 2009

(54) Image sensor and fabrication method thereof

(75) Inventors: Chien-Pang Lin, Hsinchu (TW); Chung-Jung Hsu, Hsinchu (TW); Shiu-Fang Yen, Yunlin (TW); Wu-Chieh Liu, Keelung (TW)

Correspondence Address: Joe McKinney Muncy, PO Box 1364, Fairfax, VA, 22038-1364, US

(73) Assignee: VisEra Technologies Company Limited

(21) Appl. No.: 12/010,535

(22) Filed: Jan. 25, 2008

(51) Int. Cl. H01L 27/00

(52) U.S. Cl. 250/208.1

(57) ABSTRACT

Embodiments disclose an image sensor device, comprising a substrate comprising a plurality of photosensor cells located therein or thereon, a plurality of optical guide structures corresponding to the photosensor cells respectively, and a stacked layer surrounding the optical guide structures, comprising a plurality of top portions with sharp corners adjacent to the top edges of the optical guide structures.

### BACKGROUND OF THE INVENTION

1. Field of the Invention

The present invention relates to an image sensor device, and more particularly relates to a color image sensor device with optical guide structures.

2. Description of the Related Art

Various digital imaging devices (e.g., digital cameras) use image sensors, such as charge-coupled device (“CCD”) imaging sensors and complementary metal oxide semiconductor (“CMOS”) image sensors. Such image sensors include a two dimensional array of photo-receptor devices (e.g., photodiodes), each of which is capable of converting a portion of an image to an electronic signal. Some devices (e.g., a display device) are capable of receiving one or more signals from multiple photo-receptor devices of an image sensor and forming (e.g., reconstructing) a representation of the image.

A photo-receptor device stores a signal in response to intensity or brightness of light associated with an image. Thus, for an image sensor, sensitivity to light is important.

Image sensor devices typically suffer from crosstalk, occurring when radiation over one photo-receptor device is reflected or refracted within the image sensing pixel. The reflected or refracted radiation is detected by the photo-receptor device of other pixels, thus causing picture distortion. Crosstalk is measured by providing an opaque mask over a photo-receptor device array that allows radiation (e.g., light) to enter the IC over only one underlying device. Adjacent device response is then measured and the undesired signal divided by desired signal is calculated and defined as crosstalk.

A method for reducing optical crosstalk uses techniques of optical spatial confinement and directing light onto the intended target. For instance, optical waveguides can be used to reduce the detrimental affects associated with light shields such as light piping and light shadowing. Optical waveguides, however, are not widely used to focus light directly onto the photosensor in imaging devices. Moreover, currently employed optical waveguide structures, require additional processing steps, adding to the complexity and costs of imager fabrication.

Accordingly, there is a need and desire for an improved apparatus and method for reducing optical crosstalk in imaging devices.

### BRIEF SUMMARY OF THE INVENTION

A detailed description is given in the following embodiments with reference to the accompanying drawings.

An embodiment of the invention provides an image sensor device, comprising a substrate comprising a plurality of photosensor cells located therein or thereon; a plurality of optical guide structures corresponding to the photosensor cells respectively; and a stacked layer surrounding the optical guide structures, comprising a plurality of top portions with sharp corners adjacent to the top edges of the optical guide structures.

Another embodiment of the invention provides an image sensor device, comprising: a substrate comprising a plurality of photosensor cells located therein or thereon; and a plurality of optical guide structures corresponding to the photosensor cells respectively, wherein there is substantially no gap between top edges of two adjacent optical guide structures.

A further embodiment of the invention discloses a method for forming an image sensor device, comprising: providing a substrate comprising a plurality of photosensor cells located therein or thereon; forming a stacked layer overlying the substrate; patterning the stacked layer to form a plurality of trenches corresponding to the photosensor cells respectively and leaving top portions with sharp corners between the trenches; and forming a plurality of optical guide structures in the trenches.

### BRIEF DESCRIPTION OF THE DRAWINGS

The present invention can be more fully understood by reading the subsequent detailed description and examples with references made to the accompanying drawings, wherein:

FIG. 1 to FIG. 8D are cross sections of a method for forming an image sensor according to an embodiment, illustrating fabrication steps thereof.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

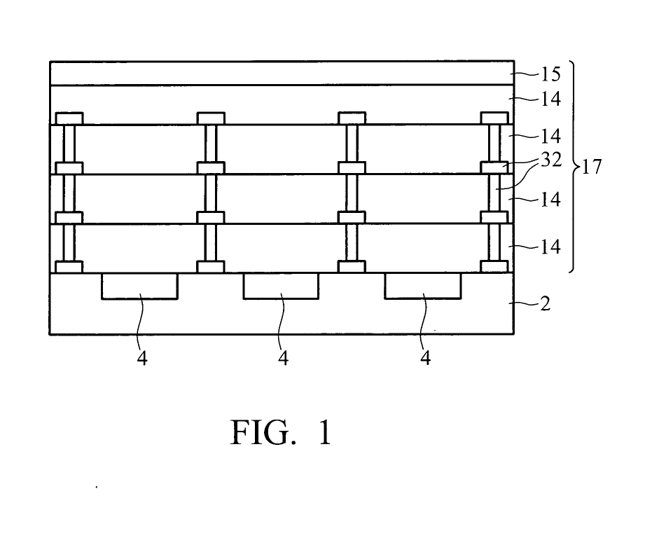

FIGS. 1 to 8D show cross sections of an exemplary embodiment of a process of fabricating an image sensor device. Wherever possible, the same reference numbers are used in the drawings and the descriptions to refer to the same or like parts.

Referring to FIG. 1, one embodiment of a substrate 2 comprises a plurality of photosensor cells 4 located therein or thereon. First, a substrate 2 is provided. In the present embodiment, the substrate 2 is a silicon substrate, but in other embodiments the substrate 2 may comprise silicon on insulator (SOI), germanium or other commonly used semiconductor substrates can be used. Then, photo-sensitive cells 4 which react to light (e.g., a light beam) are formed in the substrate 2. In one embodiment, each of the photo-sensitive cells 4 includes a PN-junction device (e.g., a diode) to convert incident light into the electric signal. Moreover, the photo-sensitive cells 4 may comprise an insulation layer (not shown) on top portions thereof. Next, a stacked layer 17 comprises a plurality of dielectric layers such as inter-metal dielectric (IMD) layers 14 formed on the photo-sensitive cells 4 and interconnections 32 formed in each of the IMD layers 14. In a preferred embodiment, the IMD layers 14 may be dielectric materials such as SiO₂ having a refractive index in the range of 1.5 to 1.6. The IMD layers 14 may be formed by atomic layer deposition (ALD), chemical vapor deposition (CVD), such as plasma-enhanced CVD (PECVD), high density plasma CVD (HDP-CVD), and low pressure CVD (LPCVD), evaporation, or any other suitable technique. The interconnections 32 may comprise metal lines and plugs thereon. Optionally, a passivation layer 15 such as silicon nitride (Si₃N₄) is formed on the IMD layers 14.

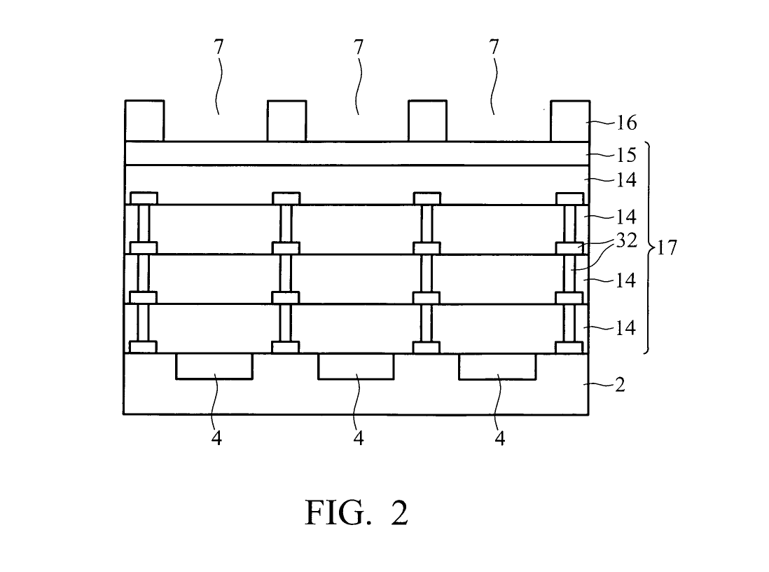

Next, referring to FIGS. 2 through 7B, cross sections illustrate a method for fabricating a plurality of optical guide structures corresponding to the photosensor cells 4 respectively formed on the substrate 2 according to an embodiment. In this embodiment, as FIG. 2 to FIG. 4 shown, the stacked layer 17 is first patterned to form a plurality of trenches such as trench 18a, trench 18b and trench 18c substantially aligned with the photo-sensitive cells 4.

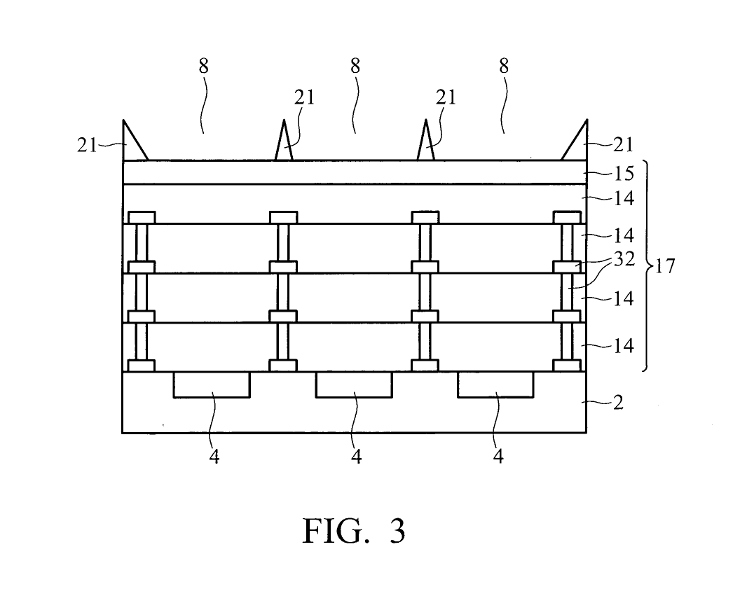

In more detail, referring to FIG. 2, the step of patterning the stacked layer 17 include forming a patterned photoresist layer 16 with openings 7 on the stacked layer 17. Then, as shown in FIG. 3, trimming the patterned photoresist layer 16 to form a triangular patterned photoresist layer 21. For example, a photolithography process to form a patterned photoresist layer 16 with openings 7 is performed to define positions of the trench 18a, trench 18b and trench 18c. A trimming process comprising an etchant with oxygen (O₂) is then performed to remove a portion of the patterned photoresist layer 16. Thus, the patterned photoresist layer 16 with openings 7 is shaped into a triangular patterned photoresist layer 21 with openings 8 on the stacked layer 17. In detail, during the trimming process of the patterned photoresist layer 16, the top portion of the patterned photoresist layer 16 will be consumed leaving a triangular patterned photoresist layer 21.

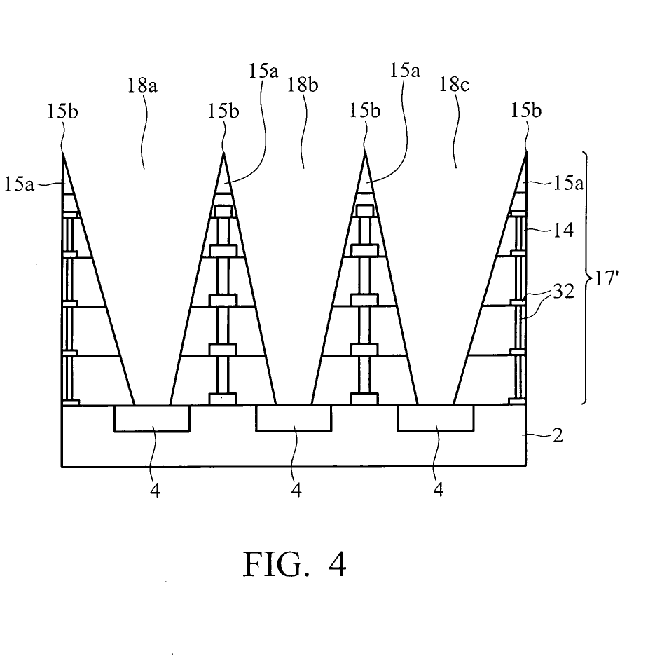

Referring to FIG. 4, etching the stacked layer 17 by using the triangular patterned photoresist layer 21 as a mask is performed. Thus, the stacked layer 17 are patterned to form a plurality of trenches 18a to 18c which corresponds to the photosensor cells 4 respectively, and leave top portions 15a with sharp corners 15b between the trenches 18a to 18c. In one example, a dry etching can be used and may be performed in the same reaction chamber as the trimming process. In a preferred embodiment, a dry etching process including an etching step and a trimming step by using the triangular patterned photoresist layer 21 as a mask is performed to remove a portion of the stacked layer 17, wherein the etching step and the trimming step are carried out in sequence. Next, the triangular patterned photoresist layer 21 is removed. Thus, a plurality of trenches 18a to 18c is formed.

Therefore, the trenches 18a, 18b and 18c are formed in the patterned stacked layer 17′ and a portion of the photo-sensitive cells 4 are exposed from the bottom of these trenches. It should be noted that the top edges of two adjacent trenches closely contact each other and the bottom edges thereof are spaced apart from each other. Also, the width of the bottom portion of these trenches is substantially smaller than or equal to the width of the photo-sensitive cells 4.

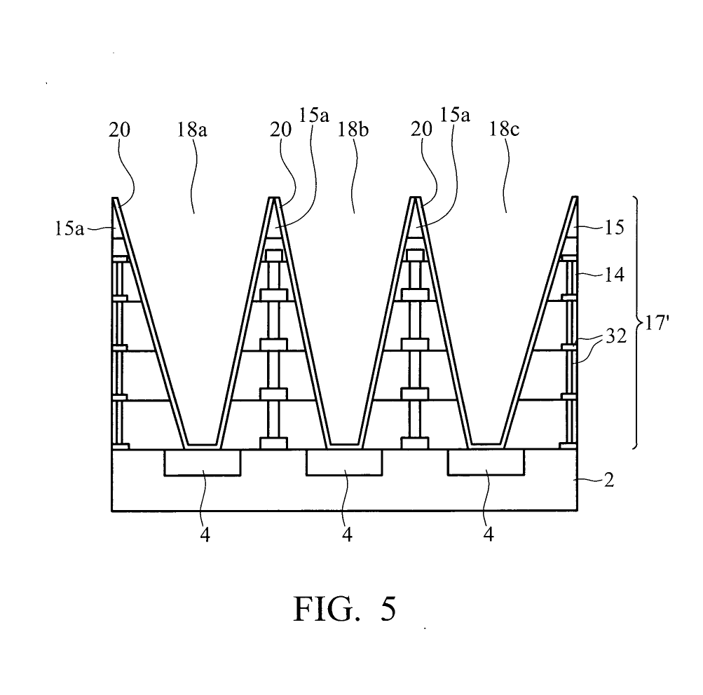

Referring to FIGS. 5 through 8, cross sections illustrate a method for fabricating the optical guide structures 70 including a plurality of light passing layers 28 overlying the photosensor cells 4 and a plurality of light-directing features 20 surrounding sidewalls of the light passing layers 28. In one example, a plurality of light-directing features 20 are then deposited over the entire substrate 2 employing known techniques and providing conformal coverage over the patterned stacked layer 17′ and the top portions 15a. Preferably, the light-directing features 20 are made of a dielectric material such as Si₃N₄ having a refractive index of about 1.6 to 1.8. In an embodiment, the light-directing features 20 are formed by using conventional CVD or PVD techniques.

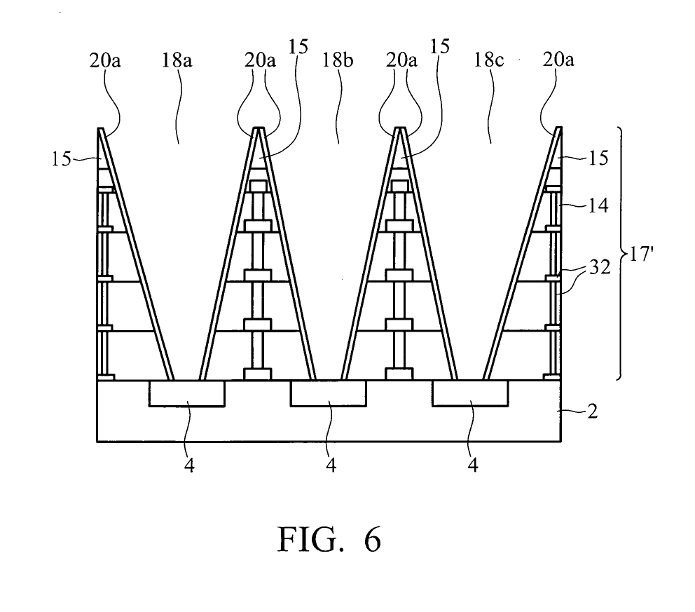

Following the embodiments described above and referring to FIG. 6, by employing methods and materials that are conventional in the art of integrated circuit fabrication for photolithography and dry etching, the light-directing features 20 may be etched away from the top surfaces of the photosensor cells 4 leaving only light-directing features 20a on sidewalls of the trenches 18a, 18b and 18c. In one embodiment, first, a patterned photoresist layer (not shown) is formed on the patterned stacked layer 17′ and a portion of the light-directing features 20 formed over the photosensor cells 4 are exposed. Then, an etching process to remove the light-directing features 20 not covered by the patterned photoresist layer is performed and thus leave only light-directing features 20a on sidewalls of the trenches 18a, 18b and 18c.

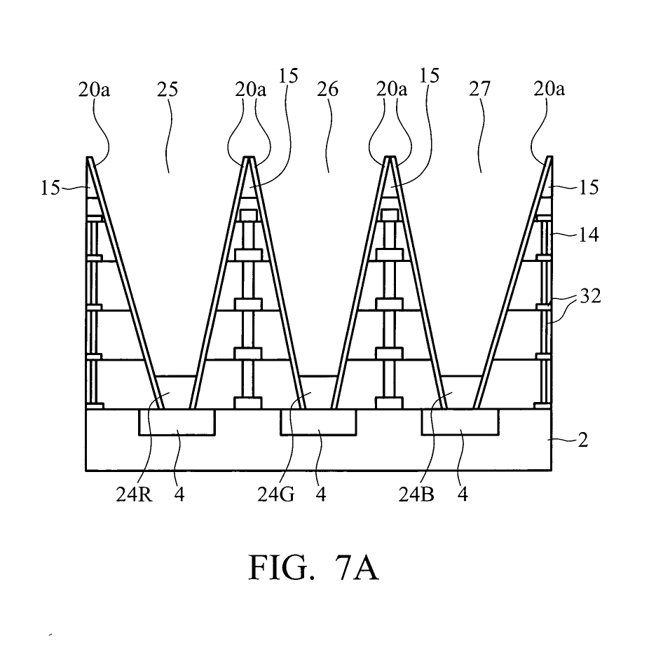

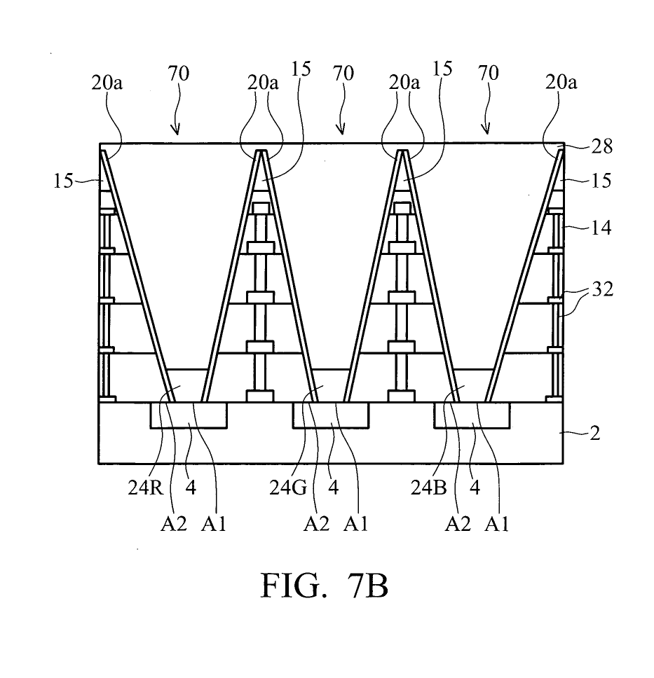

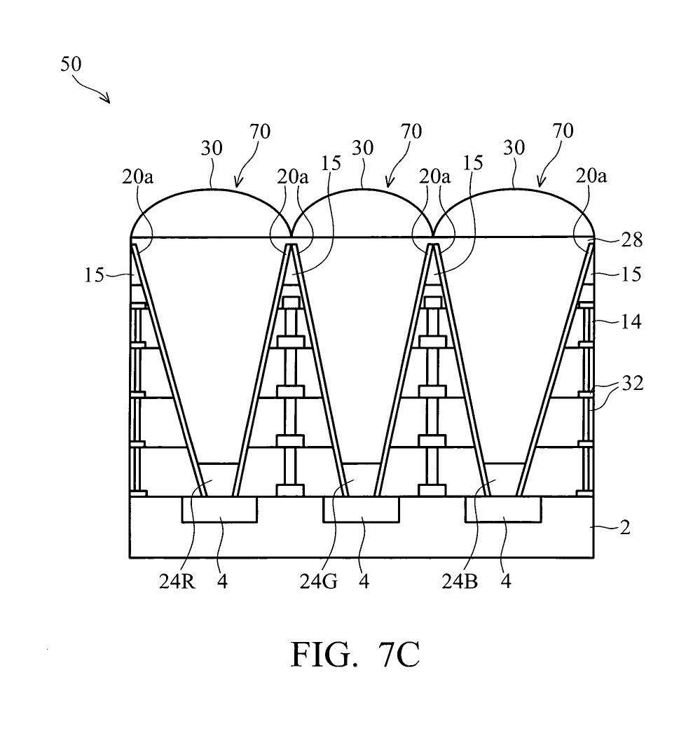

In FIG. 7A, color filter layers 24B, 24R, 24G of blue, red and green color are respectively formed in the trenches 18a, 18b and 18c corresponding to the photo-sensitive cells 4. For example, first a blue-colored layer 24B is formed in the trench 18a and then an etching back process is performed thereon, thus forming the blue-colored layer 24B with a predetermined thickness in the trench 18a and an opening 25 exposed from the trench 18a. Next, a red-colored layer 24R is formed in the trench 18b and an etching back step is then performed thereon, forming the red-colored layer 24R with a predetermined thickness in the trench 18b and an opening 26 exposed from the trench 18b. Next, a green-colored layer 24G is formed in the trench 18c and an etching back step is then performed thereon, forming the green-colored layer 24G with a predetermined thickness in the trench 18c and an opening 27 exposed from the trench 18c. Typically, the blue-colored layer 24B, the red-colored layer 24R and the green-colored layer 24G may be formed by spin coating. In a preferred embodiment, the thicknesses of the blue-colored layer 24B, the red-colored layer 24R and the green-colored layer 24G are between 0.5 μm and 1 μm.

Referring to FIG. 7B, a plurality of first light passing layers 28 are then formed on the light-directing features 20a, the blue-colored layer 24B, the red-colored layer 24R and the green-colored layer 24G, filling up the openings 25, 26 and 27, by spin coating. In a preferred embodiment, the first light passing layers 28 may comprise transparent polymers having a refractive index of about 1.5 to 1.6. It should be noted that the first light passing layers 28 has a first refractive indexes greater than that of the light-directing features 20a by at least about 0.1.

Next, etching back or chemical mechanical polishing (CMP) is performed to remove excess first light passing layers 28. Thus, the first light passing layers 28 has a substantially flat upper surface for the requirement of the subsequent process. Therefore, the first light passing layers 28 and the light-directing features 20a constitute a plurality of optical guide structures 70. It is noted that the top edges of the two adjacent optical guide structures closely contact each other and the bottom edges thereof are spaced apart from each other. In addition, overlapping areas Al between the optical guide structures and the photosensor cells 4 are equal to or smaller than areas of the sensing surfaces A2 of the photosensor cells 4.

Finally, referring to FIG. 7C, a plurality of microlenses 30 are formed on the first light passing layers 28 and aligned with the photo-sensitive cells 4 by using conventional techniques, so as to form an image sensor 50. However, the microlenses 30 may be omitted and the transmittance of the image sensor 50 may thus be enhanced, since the inputting light may be completely collected by the optical guide structures 70 without any substantial gap between the top portions thereof.

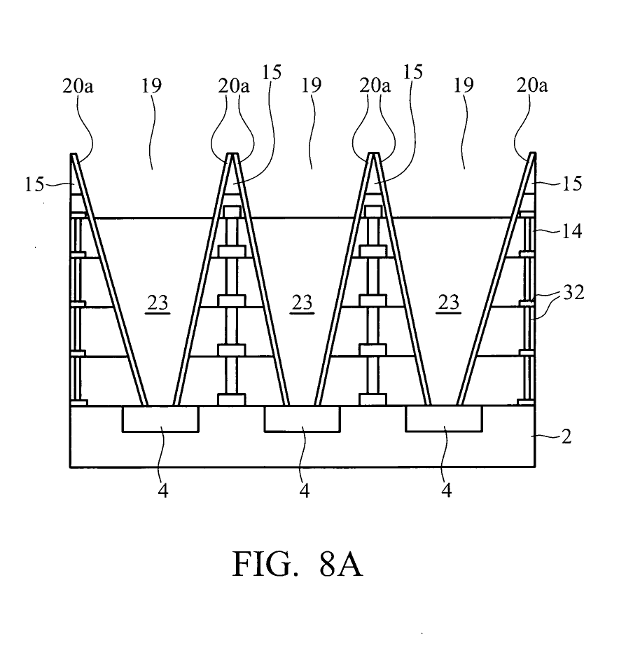

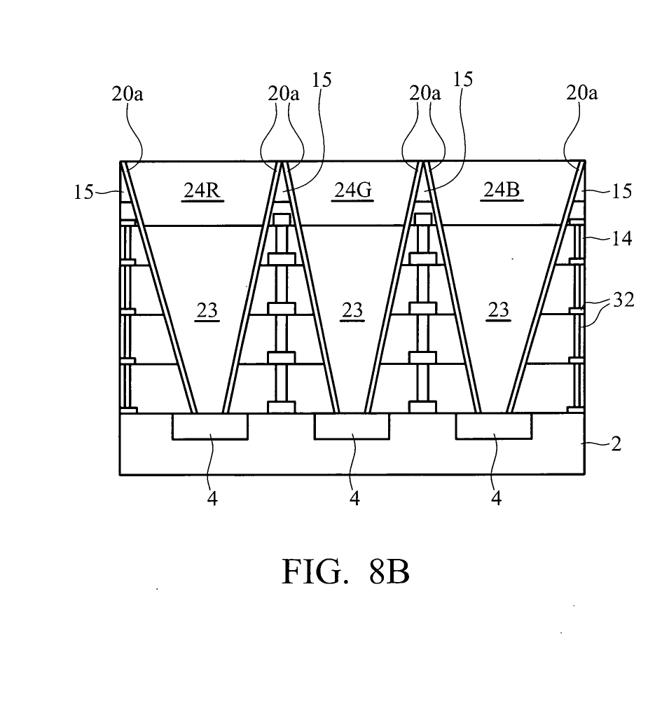

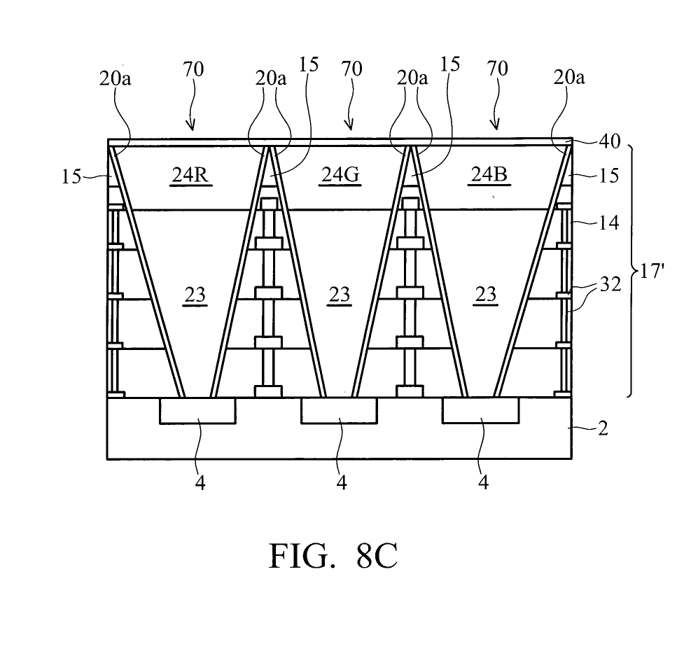

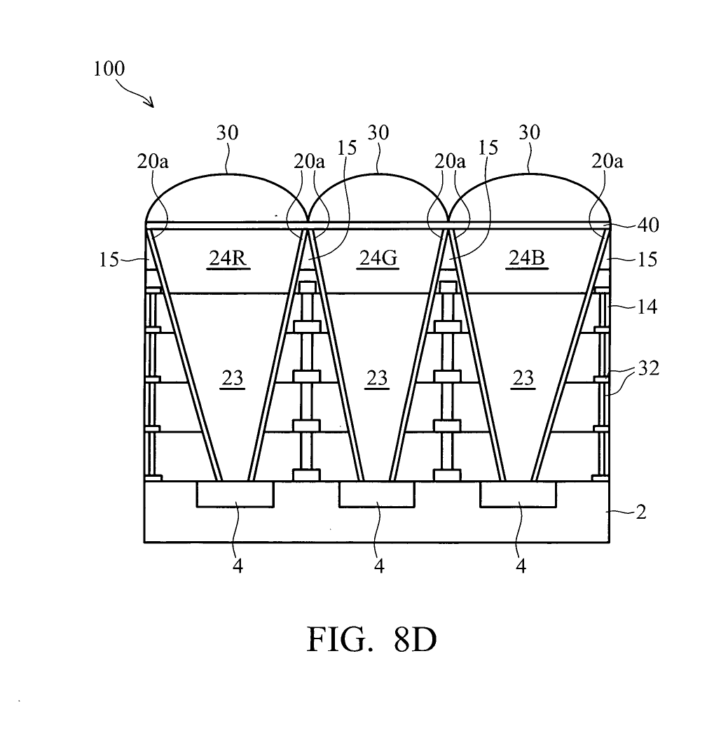

FIG. 8A to FIG. 8D show another embodiment where a plurality of second light passing layers 23 with a predetermined thickness are respectively formed in the trenches 18a, 18b and 18c before forming the blue-colored layer 24B, the red-colored layer 24R and the green-colored layer 24G in the trenches. Following FIG. 6 and referring to FIG. 8A, the second light passing layers 23 with a predetermined thickness are respectively formed in the trenches 18a, 18b and 18c and openings 19, wherein the second light passing layers 23 are exposed. The second light passing layers 23 may be formed of essentially the same materials and use essentially same methods as the first light passing layers 28. Then, a plurality of color filters is disposed in the light passing layers not higher than the top edges of the optical guide structures. Referring to FIG. 8B, the blue-colored layer 24B, red-colored layer 24R and green-colored layer 24G are respectively formed on the second light passing layers 23 and fill up the openings 19.

Next, a planarization layer is formed over the optical guide structures 70 and the patterned stacked layer 17′. As FIG. 8C shown, a third light passing layer 40 as a planarization layer is blanketly formed on the blue-colored layer 24B, the red-colored layer 24R and the green-colored layer 24G such as by spin coating. Next, etching back or chemical mechanical polishing (CMP) is performed to remove excess the third light passing layer 40. Thus, the third light passing layer 40 has a substantially flat upper surface for the requirement of the subsequent process. Preferably, the thicknesses of the blue-colored layer 24B, the red-colored layer 24R and the green-colored layer 24G are between 0.5 μm and 1 μm, and the thickness of third light passing layer 40 is substantially less than 0.25 μm.

Finally, a plurality of microlenses is optionally disposed on the optical guide structures. Referring to FIG. 8D, a plurality of microlenses 30 are formed on the third light passing layer 40 by using conventional techniques and each of the microlenses are substantially aligned with the photo-sensitive cells 4. Thus, an image sensor 100 is formed. The image sensor 100 is capable of forming (or converting) a portion of an image as an electronic signal. The image sensor 100 forms the electronic signal in response to light from an optical image, that is received through the microlenses 30, the blue-colored layer 24B (or the red-colored layer 24R or the green-colored layer 24G), and the transparent layer 23. In one embodiment, the microlenses 30 may be omitted and the transmittance of the microlenses 30 may thus be enhanced.

As described above, in order to improve sensitivity of the photo-sensitive cells 4, the light-directing features 20a are formed to fully cover trench 18a, trench 18b and trench 18c. The light-directing features 20a may improve the light reception efficiency and prevent cross-talk interference from a stray light into a neighboring trench, thereby increasing sensitivity of the photo-sensitive cells 4.

The embodiments have several other advantageous features. For example, since the color filter layers are formed in the trench, the image sensor can be minimized. Moreover, the distance of incident light from microlenses to photo-sensitive cell is shortened for the image senor. Thus, the sensitivity of the image sensor may be improved. Also, since the top edges of two adjacent optical guide structures closely contact each other, the incident light may not be shielded by the top areas between adjacent trenches. Namely, light loss can be improved by forming optical guide structures which have substantially no gap between top edges of two adjacent optical guide structures.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. An image sensor device, comprising:
a substrate comprising a plurality of photosensor cells located therein or thereon;
a stacked layer structure defining a plurality of truncated V-shaped trenches corresponding to the plurality of photosensor cells;
a light directing feature conformally disposed on sidewalls of each of the truncated V-shaped trenches and exposing the photosensor cells; and
a plurality of optical guide structures disposed in the truncated V-shaped trenches corresponding to the photosensor cells respectively, wherein the optical guide structures are directly contacted with the exposed photosensor cells.

2. The image sensor device as claimed in claim 1, wherein a plurality of top edges of two adjacent optical guide structures closely contact each other and the bottom edges thereof are spaced apart from each other.

3. The image sensor device as claimed in claim 1, wherein the optical guide structures comprise:
a plurality of light passing layers overlying the photo sensor cells.

4. The image sensor device as claimed in claim 3, wherein the optical guide structures are substantially aligned over and extended to sensing surfaces of the photosensor cells.

5. The image sensor device as claimed in claim 4, wherein overlapping areas between the optical guide structures and the photosensor cells are equal to or smaller than areas of the sensing surfaces of the photosensor cells.

6. The image sensor device as claimed in claim 3, further comprising a plurality of color filters disposed in the light passing layers not higher than the top edges of the optical guide structures.

7. The image sensor device as claimed in claim 1, further comprising a plurality of microlenses directly contacted with and disposed on a light passing layer.

8. The image sensor device as claimed in claim 3, further comprising a planarization layer over the optical guide structures and the stacked layer.

9. The image sensor device as claimed in claim 8, further comprising a plurality of microlenses on the planarization layer.

10. The image sensor device as claimed in claim 8, wherein the planarization layer is extended from the light passing layers.

11. The image sensor device as claimed in claim 3, wherein the light passing layer has a first refractive index greater than that of the light-directing features by at least about 0.1.

12. An image sensor device, comprising:
a substrate comprising a plurality of photosensor cells located therein or thereon;
a stacked layer structure defining a plurality of truncated V-shaped trenches corresponding to the plurality of photosensor cells;
a light directing feature conformally disposed on sidewalls of each of the truncated V-shaped trenches and exposing the photosensor cells; and
a plurality of optical guide structures corresponding to the photosensor cells respectively, wherein there is substantially no gap between top edges of two adjacent optical guide structures.

13. The image sensor device as claimed in claim 12, wherein there are no microlenses formed over the optical guide structures.

14. The image sensor device as claimed in claim 12, wherein there is a gap between the bottom edges of the two adjacent optical guide structures.

15-20. (canceled)
